(19) United States
(12) Patent Application Publication
(10) Pub. No.: US 2014/0085893 A1
(43) Pub. Date: Mar. 27, 2014

(54) Thermally-Managed Electronic Device

(71) Applicant: Itzhak Sapir, Irvine, CA (US)

(72) Inventor: Itzhak Sapir, Irvine, CA (US)

(21) Appl. No.: 13/625,019

(22) Filed: Sep. 24, 2012

(51) Int. Cl. H05K 7/20; F21V 29/00

(52) U.S. Cl. 362/249.02; 361/707; 361/694; 361/695; 362/249.01

(57) ABSTRACT

A thermally-managed electronic device, such as a heat-generating lamp or microelectronic assembly, takes advantage of the latent heat of phase-change within a heat pipe and functions in cooperation with a plurality of heat-radiating elements to enhance heat removal capacity from a heat source. The device, which may be provided in a natural convection or forced air convection embodiment, improves the heat removal on the cold side of the heat pipe by providing a much larger heat-radiating surface area in the form of a plurality of heat-radiating elements that are each thermally connected by means of one or more thermal connecting elements.

### CROSS-REFERENCE TO RELATED APPLICATIONS

This application claims the benefit of U.S. Provisional Patent Application No. 61/539,298, filed on Sep. 26, 2011 entitled “LED Lamp Cooling Device” pursuant to 35 USC 119, which application is incorporated fully herein by reference.

### STATEMENT REGARDING FEDERALLY SPONSORED RESEARCH AND DEVELOPMENT

N/A

### BACKGROUND OF THE INVENTION

1. Field of the Invention

The invention relates generally to the field of microelectronic and LED cooling devices and methods. More specifically, the invention relates to a thermally-managed microelectronic or LED lamp cooling assembly that uses the latent heat of phase-change inside heat pipes to significantly improve heat removal from a heat source and enhance heat removal capacity on the cold side of the heat pipe by providing increased surface area in the form of cooling fins.

2. Description of the Related Art

It is well-known that thermal management of heat-generating devices such as electronic and microelectronic assembles and lighting assemblies is a major design concern. As higher-power LED lighting assemblies and microelectronic devices (such as high-density, microelectronic modules and stacked assemblies) are coming to market, effective means to remove the heat generated by the devices is needed.

The ability to fabricate very thin, stackable layers containing one or a plurality of bare or modified homogeneous or heterogeneous integrated circuit chips is desirable and allows high-density, high-speed electronic systems to be assembled for use in military, space, security and other applications.

Examples of such layers and modules are disclosed in U.S. Pat. No. 6,072,234, entitled Stack of Equal Layer Neo-Chips Containing Encapsulated IC Chips of Different Sizes, U.S. Pat. No. 6,797,537, entitled Method of Making Stackable Layers Containing Encapsulated Integrated Circuit Chips With One or More Overlying Interconnect Layers, U.S. Pat. No. 6,784,547, entitled Stackable Layers Containing Encapsulated Integrated Circuit Chips With One or More Overlying Interconnect Layers, U.S. Pat. No. 6,117,704, entitled Stackable Layer Containing Encapsulated Chips, U.S. Pat. No. 6,072,234, entitled Stack of Equal Layer Neo-Chips Containing Encapsulated IC Chips of Different Sizes, U.S. Pat. No. 5,953,588, entitled Stackable Layers Containing Encapsulated IC Chips, and U.S. Pat. No. 7,768,113, entitled Stackable Tier Structure Comprising Prefabricated High Density Feed-through.

The stacking and interconnection of very thin microelectronic layers permits high circuit speeds in part because of short lead lengths with related reduced parasitic impedance and reduced electron time-of-flight.

These desirable features combined with a very high number of circuit and layer interconnections allow relatively large I/O designs to be implemented in a small volume but with the concomitant thermal management issue of dealing with heat dissipation in the range of up to 40 watts per module. Similarly, thermal management issues arise with the use of high-power transistor or resistor elements in higher-power electronic systems

Conventional heat sinks, fans and finned elements are unable to adequately remove sufficient thermal energy from these state of the art, high-power devices.

A thermally-managed device for removal of excess heat from such devices is needed to overcome these and other deficiencies in the prior art.

### BRIEF SUMMARY OF THE INVENTION

The invention is a thermally-managed electronic device, such as a heat-generating lamp or microelectronic assembly, that takes advantage of the latent heat of phase-change within a heat pipe and functions in cooperation with a plurality of heat-radiating elements to enhance heat removal capacity from a heat source.

The device of the invention, which may be provided in a natural convection or forced air convection embodiment, improves heat removal on the cold side of the heat pipe by providing a much larger heat-radiating surface area in the form of a plurality of heat-radiating elements that are each thermally connected by means of one or more thermal connector elements.

Heat pipe technology is known with many design and analysis tools and manufacturers available. The disclosed device takes advantage of this known technology in a new application field and structure.

In a first aspect of the invention, a thermally-managed electronic device is disclosed comprising a heat source element, a heat plate in thermal connection with the heat source element, a heat pipe having a hot end and a cold end and that is configured so that the hot end is in thermal connection with the heat plate and so that the cold end is in thermal connection with a heat-radiating element such as a heat-conducting fin.

In a second aspect of the invention, the cold end is in thermal connection with the heat-radiation element by means of a thermal connector element.

In a third aspect of the invention the thermal connector element is in thermal connection with a plurality of the heat-radiating elements.

In a fourth aspect of the invention, the heat source element comprises at least one LED lighting element.

In a fifth aspect of the invention, the heat source element comprises at least one incandescent lighting element.

In a sixth aspect of the invention, the device further comprises a forced air element configured to remove heat from the heat-radiating element to the environment.

In a seventh aspect of the invention, the forced air element is a fan element.

In an eighth aspect of the invention, a device disclosed wherein the heat source element comprises an electronic component, a heat plate in thermal connection with the electronic component, a heat pipe having a hot end and a cold end, the hot end in thermal connection with the heat plate and the cold end in thermal connection with a heat-radiating element.

In a ninth aspect of the invention, the thermal connector element is in thermal connection with a plurality of the heat-radiating elements.

In a tenth aspect of the invention, the electronic component comprises a stacked microelectronic assembly.

In an eleventh aspect of the invention, the electronic component comprises a transistor element.

In a twelfth aspect of the invention, the electronic component comprises a resistor element.

These and various additional aspects, embodiments and advantages of the present invention will become immediately apparent to those of ordinary skill in the art upon review of the Detailed Description and any claims to follow.

While the claimed apparatus and method herein has or will be described for the sake of grammatical fluidity with functional explanations, it is to be understood that the claims, unless expressly formulated under 35 USC 112, are not to be construed as necessarily limited in any way by the construction of “means” or “steps” limitations, but are to be accorded the full scope of the meaning and equivalents of the definition provided by the claims under the judicial doctrine of equivalents, and in the case where the claims are expressly formulated under 35 USC 112, are to be accorded full statutory equivalents under 35 USC 112.

### BRIEF DESCRIPTION OF THE SEVERAL VIEWS OF THE DRAWINGS

FIG. 1 shows the device of the invention in a natural convection embodiment.

FIG. 2 shows a cross-section of the natural convection embodiment of the device of the invention.

FIG. 3 shows the device of the invention in a forced-air convection embodiment.

FIG. 4 shows a cross-section of the forced-air convection embodiment of the device of the invention.

The invention and its various embodiments can now be better understood by turning to the following detailed description of the preferred embodiments which are presented as illustrated examples of the invention defined in the claims.

It is expressly understood that the invention as defined by the claims may be broader than the illustrated embodiments described below.

### DETAILED DESCRIPTION OF THE INVENTION

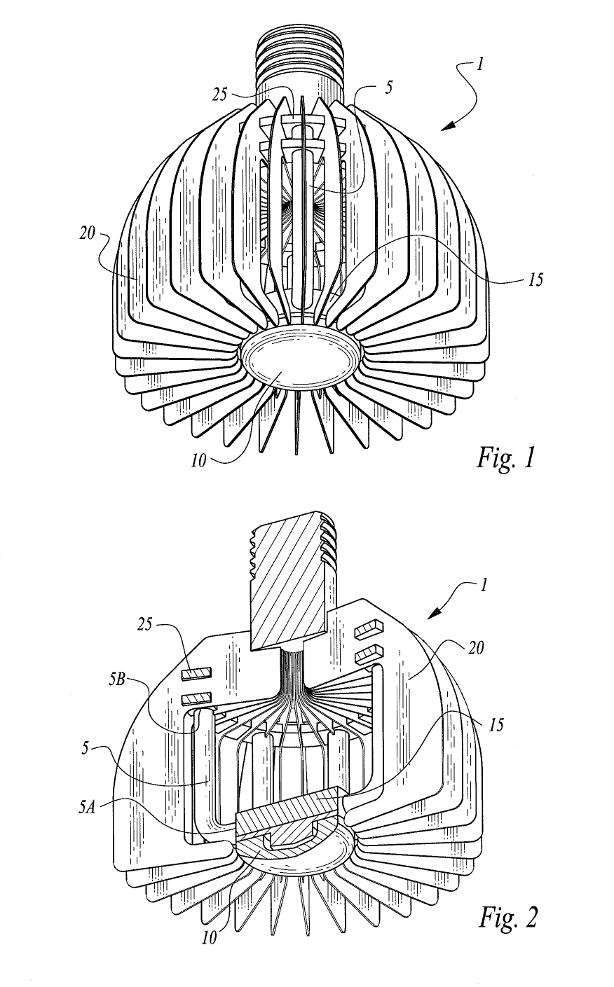

Turning now to the figures wherein like references define like elements among the several views, Applicant discloses a thermally-managed electronic device 1 such as an LED lamp assembly or microelectronic assembly with active heat removal using a heat-pipe 5 in cooperating with a heat source element 10 such as an LED lamp or microelectronic module or electronic component as is shown in FIGS. 1-4.

It is expressly noted that the heat source element 10 of the claims of the invention is not limited to an LED or incandescent lamp or microelectronic module or electronic component, but rather may comprise any element that acts as a heat source including without limitation any mechanical, electrical or chemical source of heat.

FIGS. 1 and 2 depict the device 1 of the invention having a heat source element 10 in a natural convection embodiment.

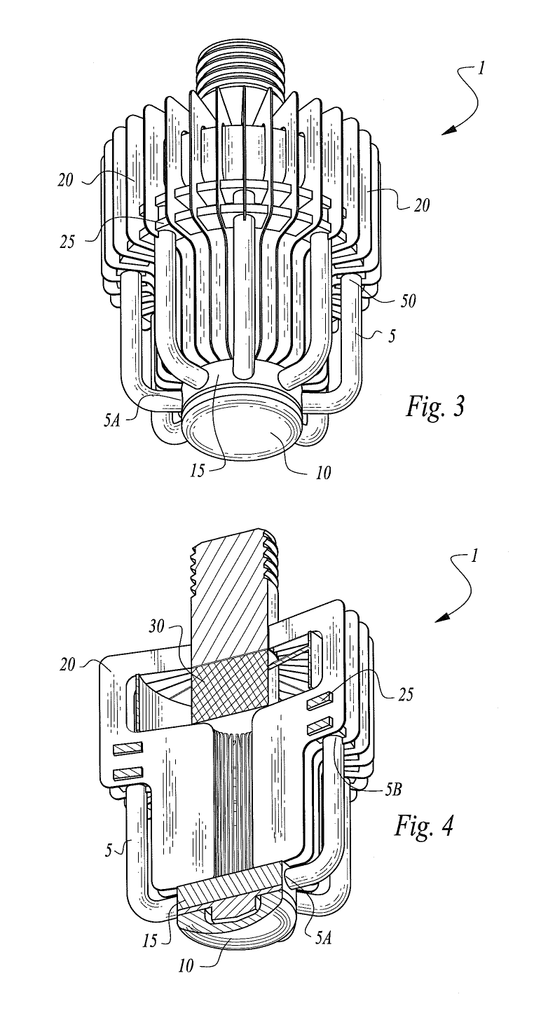

FIGS. 3 and 4 depict device 1 of the invention having a heat source element 10 in a forced-air convection embodiment.

As reference above, device 1 takes advantage of “heat pipes” 5 as a heat removal elements for achieving a thermal performance advantage over prior art heat-radiating elements such as solid metal fins.

By way of background, a heat pipe is an engineered heat-transfer device typically provided in the shape of a straight or bent metal tube. A heat pipe combines and takes advantage of the principles of thermal conductivity and liquid-gas “phase-change” to efficiently transfer heat between two solid interfaces. A heat pipe contains a liquid under low pressure and a “wick” material disposed within a sealed interior volume.

The combination of low pressure and the type of liquid therein determines the evaporation temperature of the internal liquid when heated. The “hot end” 5A of heat pipe 5 is in thermal contact with heat source element 10 which may be by means of a thermally conductive heat plate 15 that is in thermal contact with heat source element 10.

The “cold end” 5B of heat pipe 5 is in thermal communication with a heat-radiating element 20 which may be provided in the form of one or more thermally-conductive convection fins. Cold end 5B is preferably in thermal communication with heat-radiating element 20 by means of one or more thermal connecting elements 25. Thermal connecting elements 25 are thermally-conducive mechanical fasteners configured to efficiently transfer heat across and to the heat-radiating elements 20 to which they are connected.

During operation, the liquid within heat pipe 5 turns into vapor by absorbing heat from heat source element 10. The vapor expands to the cold end 5B of heat pipe 5 where it condenses back into liquid, releasing the latent heat into heat-radiating element 20.

The liquid then returns to hot end 5A of heat pipe 5 through either capillary action (the inner wick), by gravity action or both. The liquid within heat pipe 5 then evaporates in a repeated cycle and the heat transfer process through heat pipe 5 continues.

Two primary advantages of the use of heat pipes 5 over heat-radiating elements 20 individually is that latent heat of evaporation absorbs significant amounts of thermal energy very quickly and the evaporation temperature is substantially maintained all the way to the cold end 5B of heat pipe 5 structure (i.e., evaporation and condensation temperatures are substantially identical). This feature permits a relatively large AT with respect to the ambient air temperature in a large area of cold end 5B.

The natural convection embodiment of FIGS. 1 and 2 illustrates a passive thermal transfer system that is suitable for heat dissipation requirements in lower-power electronic devices or LED lighting assemblies. Preferably, in the natural convection embodiment of FIGS. 1 and 2, heat-radiation elements 20 (i.e., thermally-conductive fins) have a large surface area on the outer side of the assembly to permit a natural convection heat flow to develop.

An alternative preferred forced-air embodiment of device 1 is also disclosed and is suitable for use in higher-power applications or when a more physically compact design is required. In the forced-air convection cooled embodiment shown in FIGS. 3 and 4, a forced air element 30 such as a low-power, low-noise, long-life, miniature fan element is provided to force cooling air along and through heat-radiating elements 20 that are in thermal communication with or are attached to cold end 5B of the heat pipes 5. Heat-radiating elements 20, shown as fins, thus occupy the inner volume between heat pipes 5 since there is no need for natural convection flow to develop.

Many alterations and modifications may be made by those having ordinary skill in the art without departing from the spirit and scope of the invention. Therefore, it must be understood that the illustrated embodiment has been set forth only for the purposes of example and that it should not be taken as limiting the invention as defined by the following claims. For example, notwithstanding the fact that the elements of a claim are set forth below in a certain combination, it must be expressly understood that the invention includes other combinations of fewer, more or different elements, which are disclosed above even when not initially claimed in such combinations.

The words used in this specification to describe the invention and its various embodiments are to be understood not only in the sense of their commonly defined meanings, but to include by special definition in this specification structure, material or acts beyond the scope of the commonly defined meanings Thus if an element can be understood in the context of this specification as including more than one meaning, then its use in a claim must be understood as being generic to all possible meanings supported by the specification and by the word itself.

The definitions of the words or elements of the following claims are, therefore, defined in this specification to include not only the combination of elements which are literally set forth, but all equivalent structure, material or acts for performing substantially the same function in substantially the same way to obtain substantially the same result. In this sense it is therefore contemplated that an equivalent substitution of two or more elements may be made for any one of the elements in the claims below or that a single element may be substituted for two or more elements in a claim. Although elements may be described above as acting in certain combinations and even initially claimed as such, it is to be expressly understood that one or more elements from a claimed combination can in some cases be excised from the combination and that the claimed combination may be directed to a subcombination or variation of a subcombination.

Insubstantial changes from the claimed subject matter as viewed by a person with ordinary skill in the art, now known or later devised, are expressly contemplated as being equivalently within the scope of the claims. Therefore, obvious substitutions now or later known to one with ordinary skill in the art are defined to be within the scope of the defined elements.

The claims are thus to be understood to include what is specifically illustrated and described above, what is conceptually equivalent, what can be obviously substituted and also what essentially incorporates the essential idea of the invention.

We claim:

1. A thermally-managed electronic device comprising:
a heat source element,
a heat plate in thermal connection with the heat source element,
a heat pipe having a hot end and a cold end,
the hot end in thermal connection with the heat plate, and,
the cold end in thermal connection with a heat-radiating element.

2. The device of claim 1 wherein the cold end is in thermal connection with the heat-radiating element by means of a thermal connector element.

3. The device of claim 2 wherein the thermal connector element is in thermal connection with a plurality of the heat-radiating elements.

4. The device of claim 3 wherein the heat source element comprises at least one LED lighting element.

5. The device of claim 3 wherein the heat source element comprises at least one incandescent lighting element.

6. The device of claim 3 further comprising a forced air element configured to remove heat from the plurality of heat-radiating elements to the environment.

7. The device of claim 6 wherein the forced air element is a fan element.

8. A thermally-managed electronic assembly comprising:
a heat source element comprising an electronic component,
a heat plate in thermal connection with the electronic component,
a heat pipe having a hot end and a cold end,
the hot end in thermal connection with the heat plate, and,
the cold end in thermal connection with a heat-radiating element.

9. The device of claim 8 wherein the cold end is in thermal connection with the heat-radiating element by means of a thermal connector element.

10. The device of claim 9 wherein the thermal connector element is in thermal connection with a plurality of the heat-radiating elements.

11. The device of claim 10 wherein the electronic component comprises a stacked microelectronic assembly.

12. The device of claim 10 wherein the electronic component comprises a transistor element.

13. The device of claim 10 wherein the electronic component comprises a resistor element.
